(19) United States
(12) Patent Application Publication
(10) Pub. No.: US 2007/0252747 A1
(43) Pub. Date: Nov. 1, 2007

(54) No-missing-code analog to digital converter system and method

(76) Inventors: Colin Lyden, Co. Cork (IE); Paraic Brannick, Co. Mayo (IE); Alain Valentin Guery, Andover, MA (US)

Correspondence Address: IANDIORIO & TESKA;INTELLECTUAL PROPERTY LAW ATTORNEYS, 260 BEAR HILL ROAD, WALTHAM, MA, 02451-1018, US

(21) Appl. No.: 11/413,314

(22) Filed: Apr. 28, 2006

(51) Int. Cl. H03M 1/38

(52) U.S. Cl. 341/161

(57) ABSTRACT

A no-missing-code output from a SAR, pipeline, folding, flash analog to digital conversion can be obtained by providing an analog input to an analog to digital converter having a predetermined m bit resolution output and a predetermined missing code capability and generating in a digital filter from the m bit output and the dither of the random noise components of the m bit output n bit output and greater than the predetermined missing code capability of the analog to digital converter.

### FIELD OF THE INVENTION

This invention relates to a no-missing-code analog to digital converter system and method for e.g. SAR, pipeline, flash, and folding analog to digital converters.

### BACKGROUND OF THE INVENTION

In analog to digital converters (ADC's) the transfer function is of code against input voltage where code is the dependent variable and voltage input is the independent value. Ideally each step is one LSB wide. The deviation in the position of the center of the step from the ideal is called integral non-linearity (INL). INL is generally expressed in fractions of LSB. DNL is the difference between the INLs of consecutive steps. The ideal is an INL and a DNL of zero. For example, with adjacent INLs of −0.2 LSB and +0.2 LSB the DNL is:
DNL=INL (N₁)−INL (N₂)
DNL=−0.2−(+0.2)
DNL=−0.4 LSB
This means that the step is −0.4 LSB smaller than it ought to be. At a DNL of −1.0 the code will be missing from the transfer function which is disruptive in, for example, a digital closed loop control system. Having no missing code (NMC) is highly desirable.

In conventional successive approximating register (SAR) ADC's these missing code conditions occur because of manufacturing variations in the component values. This requires very careful processing and/or calibration during fabrication. The calibrations can be done in the fabrication process but once in the field the normal drift over time and temperature could again cause missing codes. Because of this many SAR, flash, folding, pipeline ADC's are presently limited to 12-16 bit accuracy. For accuracy beyond that ΣΔ ADC's may be used. One bit ΣΔ ADC's convert an analog input to a digital output then convert that digital output to an analog signal and feed it back to be summed with the analog input. Any difference in the analog input and the analog feedback causes the ADC to create more or fewer digital pulses. The pulse density or rate at any time is a digital representation of the analog input. The same principle of operation applies to multi-bit and higher order ΣΔ ADC's. ΣΔ conversion introduces a large amount of quantization noise which is predominately outside the frequency band of interest. And so it is a common practice to use a low pass filter to remove the majority of that quantization noise. Generally ΣΔ ADC's require a larger area and are less efficient than SARs or other ADC's. In all types of ADCs there is an advantage from over sampling i.e. sampling at more than twice the signal bandwidth. However, in many applications the high output rates chip to chip which result from over sampling are undesirable.

### SUMMARY OF THE INVENTION

It is therefore an object of this invention to provide an improved no-missing-code analog to digital converter system and method for SAR, pipeline, flash, and folding analog to digital converters.

It is a further object of this invention to provide such an improved no-missing-code analog to digital converter system and method which provides a dramatic improvement in DNL.

It is a further object of this invention to provide such an improved no-missing-code analog to digital converter system and method with improved no-missing-code performance.

It is a further object of this invention to provide such an improved no-missing-code analog to digital converter system and method which uses an integral on-chip digital filter which can reduce chip to chip data rates while maintaining high internal on-chip sample rates and accuracy.

It is a further object of this invention to provide such an improved no-missing-code analog to digital converter system and method which can employ over sampling rates to spread the noise spectrum and then use band limited filtering to remove the out-of-band noise with a resulting reduction in band errors.

The invention results from the realization that a virtually no-missing-code analog to digital converter with increased, decreased or the same resolution can be achieved by utilizing the dither of random noise such as thermal noise, or intentionally introduced noise e.g., from a pseudorandom noise generator, to drive a digital filter as an integral part of the analog to digital converter system to recover the missing codes as a function of the number of taps in the filter and the further realization that the number of codes can also be increased and presented as the system output to subsequent and off-chip components.

The subject invention, however, in other embodiments, need not achieve all these objectives and the claims hereof should not be limited to structures or methods capable of achieving these objectives.

This invention features an SAR/pipeline/flash/folding no-missing-code analog to digital converter system including an analog to digital converter having a significant random noise component relative to its LSB and having a predetermined missing code capability. There is a digital filter responsive to the dither introduced by the random noise components of the m bit inputs from the analog to digital converter to provide n bit outputs and greater than the predetermined missing-code capability of the analog to digital converter.

In a preferred embodiment the digital filter and the analog to digital converter may be on a single chip. m may be greater than n and the filter may reduce resolution and recover missing codes. m may be equal to n and the filter may recover missing codes. m may be less than n and the filter may increase resolution and recover missing codes. The digital filter may include one of a group of low pass, bandpass, highpass, stopband, sinc, IIR, and FIR filters. There may be a truncating circuit for reducing the output bit resolution from the digital filter to a pre-selected lower resolution. There may be an output circuit for delivering the no-missing-code output of the digital filter off-chip as an output of the system. The digital filter may include a plurality of taps for band limiting the m bit inputs. It may include a plurality of taps for averaging the m bit inputs. The digital filter may increase word width as a function of the number of taps. It may increase missing code recovery in each successive stage as a function of the number of taps. The random noise may include significant thermal noise. The analog to digital converter may include a random noise source for contributing to the random noise. There may be a first mux circuit for selectively providing a number of different inputs to the analog to digital converter, a plurality of digital filters and a second mux circuit for selectively connecting the analog to digital converter to one of the digital filters.

This invention also features a method of providing a no-missing-code output from an analog to digital converter system including providing an analog output to an analog to digital converter having a predetermined m bit resolution output and predetermined missing code capability, and delivering the m bit output to a digital filter. The digital filter generates from the m bit output and the dither of the random noise components of the m bit output n bit output and greater than the predetermined missing code capability of the analog to digital converter.

In a preferred embodiment the digital filter and the analog to digital converter may be on a single chip. m may be greater than n and the filter may reduce resolution and recover missing codes. m may equal to n and the filter may recover missing codes. m may be less than n and the filter may increase resolution and recover missing codes. The output bit resolution from the digital filter may be reduced to a pre-selected lower resolution. The digital filter may include a plurality of taps for band limiting or averaging the m bit inputs. The digital filter may increase word width as a function of the number of taps and it may increase missing code recovery in each successive stage as a function of the number of taps. The random noise may include significant thermal noise and the analog to digital converter may include a random noise source for contributing to the random noise.

### BRIEF DESCRIPTION OF THE DRAWINGS

Other objects, features and advantages will occur to those skilled in the art from the following description of a preferred embodiment and the accompanying drawings, in which:

FIG. 1 is a simplified schematic block diagram of an analog to digital converter system according to this invention;

FIG. 2 is a more detailed schematic block diagram of one implementation of the analog to digital converter (ADC) of FIG. 1 using a successive approximation register (SAR) analog to digital converter;

FIG. 3 illustrates a typical transfer function of the analog to digital converter of FIGS. 1 and 2;

FIG. 4 is a more detailed view of one implementation of the digital filter of FIG. 1;

FIG. 5 is a histogram of probability versus code for a nearly missing code;

FIG. 6 is a view similar to FIG. 5 with the input shifted slightly;

FIG. 7 is a graphical illustration of an INL function of an analog to digital converter system not employing this invention;

FIG. 8 is a view similar to FIG. 7 of an INL function of an analog to digital converter system employing this invention;

FIG. 9 is a graphical illustration of a DNL function of an analog to digital converter system not employing this invention;

FIG. 10 is a view similar to FIG. 9 of a DNL function of an analog to digital converter system employing this invention; and

FIG. 11 is an ADC system with multiplexed inputs and multiplexed outputs to a number of digital filters according to this invention; and

FIG. 12 is a block diagram of the method according to this invention.

### DISCLOSURE OF THE PREFERRED EMBODIMENT

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

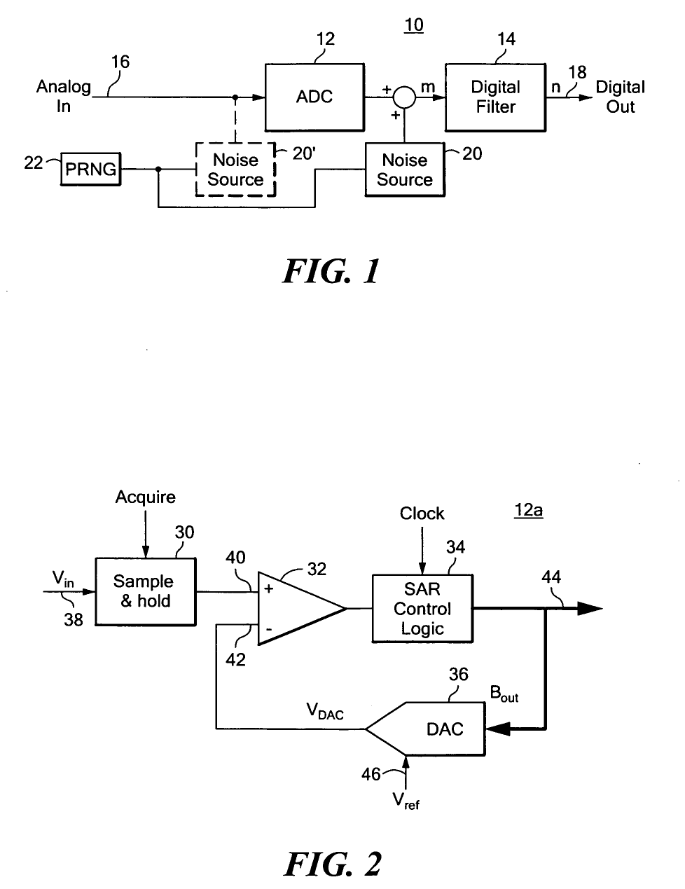

There is shown in FIG. 1 a no-missing-code analog to digital converter system 10 according to this invention including an analog to digital converter 12 and digital filter 14. The analog input is provided on line 16 to ADC 12 whose digital output is provided to digital filter 14 which in turn provides a digital output on line 18. In accordance with this invention an external noise source 20 may be applied to the output of ADC 12 or to its input 20′ in keeping with this invention. Analog to digital converters may have, as an example, a twelve or thirteen bit resolution and a predetermined propensity to have a 90% probability for no missing codes. In accordance with this invention either source 20 or 20′ may be actuated intermittently by a pseudorandom noise generator 22. Analog to digital converter 12 may include a number of different kinds of analog to digital converters, for example, successive approximation register (SAR), pipeline, flash, or folding.

In this particular embodiment ADC 12 may be implemented with a SAR ADC12a, FIG. 2, which includes a sample and hold circuit 30 comparator 32, SAR logic circuit 34 and digital to analog converter (DAC) 36. SAR ADC 12a operates in a conventional manner by receiving an input analog voltage Vᵢₙ at input 38 and sampling and holding it while providing it to one input 40 of comparator 32. SAR control logic 34 generates a code which represents midrange. This code is converted by DAC 36 to an analog voltage which is delivered at input 42 of comparator 32. Comparator 32 then provides an output to SAR control logic 34 which indicates whether the DAC voltage VDAC on line 42 is greater than or lesser than the input voltage on line 40. If it is less, SAR control logic 34 generates another code which is halfway between the voltage on line 42 and the voltage on line 46 and that voltage is provided through DAC 36 to line 42. SAR ADC 12a continues in this fashion in half steps up and down successively approximating the voltage on line 40. The result is provided on output line 44 as the digital representation of the input voltage Vᵢₙ on line 38. The digital filter may be of any suitable type, e.g. low pass, bandpass, highpass, stopband; sinc, IIR, FIR.

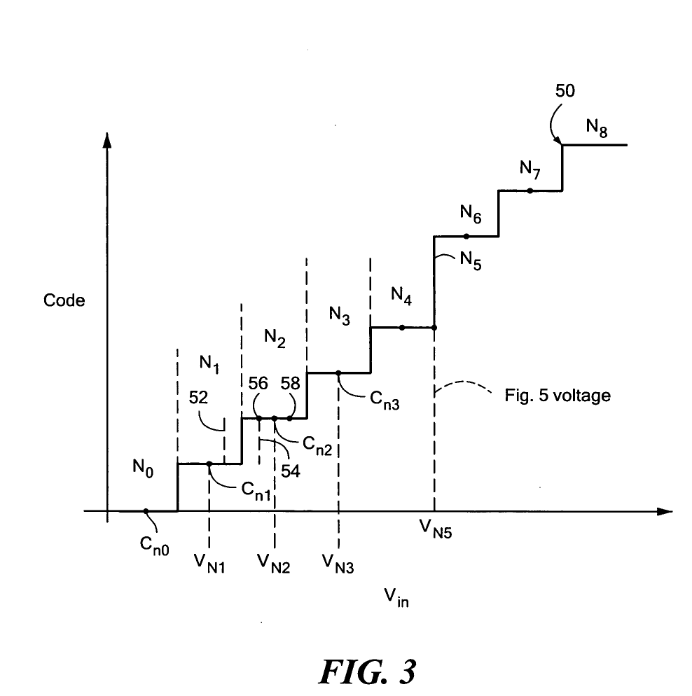

The transfer function of an ADC is shown in FIG. 3, where code is the dependent variable and the voltage in is the independent variable. Ideally each step is one LSB wide. However, this is not always the case. Due to processing variation, for example, the steps are not always equal or correctly positioned. The deviation and the position of the center of the step from the ideal is called the integral non-linearity (INL). INL is generally expressed in fractions of LSBs. In FIG. 3, transfer characteristic 50 is shown with each of the centers ideally situated in the center of the step Cₙ_{₀}, Cₙ_{₁}, Cₙ_{₂}, Cₙ_{₃}, and so on. It can be seen, however, that in less than ideal situations step N₂ may be wider 52, or narrower 54, than the ideal in which case the center will be shifted as at 56 and 58, respectively. The amount of the shift is expressed in fractions of LSBs and the direction by using a minus or a plus. The difference between the INLs of consecutive steps is known as the differential non-linearity or DNL. The ideal for both INL and DNL is zero. That is, DNL equals the INL of step N₁ minus the INL of step N₂. Suppose the INL of step N₁ is −0.2 LSB and that of step N₂ is +0.2 LSB, this gives the DNL of −0.4 LSB. This means that the step is −0.4 LSB smaller that it ought to be. A minus DNL is always a concern. For at a DNL of −1 LSB the code will be missing from the transfer function. For example, in FIG. 3, due to a processing defect, step N₅ does not appear. Thus, if one put in the voltage for Vₙ_{₁} or Vₙ_{₂} or Vₙ_{₃} et seq. the particular code for that step would occur. However, putting in the voltage Vₙ_{₅} gives no such code, there is only a code for N₄ and N₆. There is thus, a missing code.

This invention results from the appreciation that a no-missing-code analog to digital converter with increased, decreased, or the same resolution can be achieved by using the dither of random noise, such as thermal noise, that is associated with the analog to digital converter. If the random noise, thermal or other, isn't sufficient, noise can be intentionally introduced, for example, using a pseudorandom noise generator. The output of the analog to digital converter and the dither of the noise can be used by a digital filter as an integral part of the analog to digital converter system to recover the missing codes as a function of the number of taps in the filter. The dither associated with this noise can also be used to increase the number of codes available and thus the accuracy of the system. And further, this increased accuracy and increased number of codes can be presented as the system output to subsequent and off-chip components.

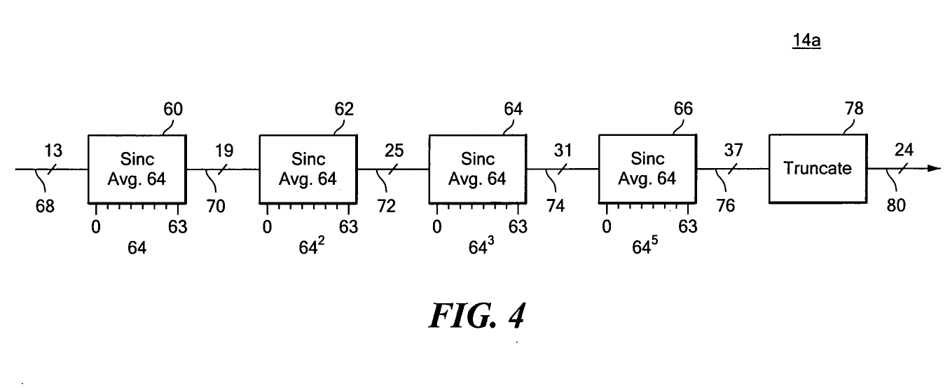

This is done simply by employing a digital filter to band limit or to average the output of the analog to digital converter. For example, in one implementation digital filter 14a may include one or more sinc filters stages, 60, 62, 64, and 66, FIG. 4. This operates in the following way, suppose for example the m bit output from the analog to digital converter on line 68 was a thirteen bit output but one of the codes was missing. The first sinc stage 60 does an average of, for example, sixty-four sample and hold cycles. Adding sixty-four thirteen bit numbers and then dividing by sixty-four results in a nineteen bit output from stage 60. Continuing in this way, stage 62 would add sixty-four nineteen bit numbers from its input on line 70 which would produce a twenty-five bit output on line 72. Each time the average sixty-four operation is conducted in a stage the number of bits in the output will be increased by a proportional number. Word width increases as a function of the number of taps. For example, since sixty-four is represented as 2⁶ in binary, the number of output bits increases by six. If the stages were operating with a thirty-two average the outputs would go up by five bits: if 128 by seven bits. In short, the word increases as the power of the radix: for 64 or 2⁶ the word width increases by 6, for 32 or 2⁵ the word width increase by 5, for 128 or 2⁷ the word width increases by 7. This continues in stage 64 whose output is now at thirty one bits and stage 66 whose output is at thirty-seven bits. Thus the output resolution has increased dramatically. In addition, if there is a missing code, for example, in the original thirteen so that there are only twelve codes rather than thirteen it is not a major detriment since the nineteen bits on line 70 would merely be eighteen and the twenty-five bits on line 72 would be twenty-four. The thirty-one bits on line 74 would be thirty. The thirty-seven bits on line 76 would be thirty-six bits. Further, assuming that the number of bits is increased in this way, there is guaranteed to be no missing code.

The band limiting filter improves the no-missing-code resolution only if the analog to digital converter's output is time varying. If the converter output is constant, then each of its possible outputs will lead to a unique output from the filter, and the no-missing-code resolution of the converter plus filter will be identical to that of un-filtered converter. As mentioned earlier, thermal and other circuit noise sources ensure that the outputs of most modem high accuracy analog to digital converters are always time varying, even if the corresponding input is constant. Alternatively, the designer may chose to insert noise into the converter using techniques such as dither.

In addition, there may well be more accuracy than is required, for example, few applications presently require a thirty-seven bit accuracy. For this purpose a truncating circuit 78 may be used to reduce the output bits to some desired size. For example, twenty-four bits as shown on output line 80. Truncating circuit 78 could be a register with just twenty-four bit capability or it could be just a group of output conductors where there are just twenty-four conductors not thirty-seven and the remaining thirteen outputs are simply not propagated.

It has been found that the longer the filter is the better it fills in the missing codes. It is the number of taps overall that control the improvement in the missing code capability as well as increasing the accuracy. Thus by either increasing the number of stages 60, 62, 64, or 66 or the number averaging or band limiting operations per stage, the accuracy and the no-missing code capability is increased. Preferably ADC 12 and digital filter 14, FIG. 1, are on a single chip so that the ADC 12 and digital filter 14, together, appear as the analog to digital converter system which delivers a no-missing-code output off-chip as an output of the system and with whatever increase in accuracy is desired. No matter whether the m inputs to the digital filter 14 are greater, lesser, or equal to the n bit output of digital filter 14 the missing codes will be recovered. The only difference is where m is greater than n there will be an increase in resolution or accuracy as well. Where m is less than n there will be a decrease in resolution and where m is equal to n there will be no change in resolution. Typically, random noise with a standard deviation exceeding say one-half an LSB, will recover missing codes and increase accuracy. The random noise may have a significant component of thermal noise. Here again by significant is meant a standard deviation equal to about one-half of the random noise or one-quarter LSB.

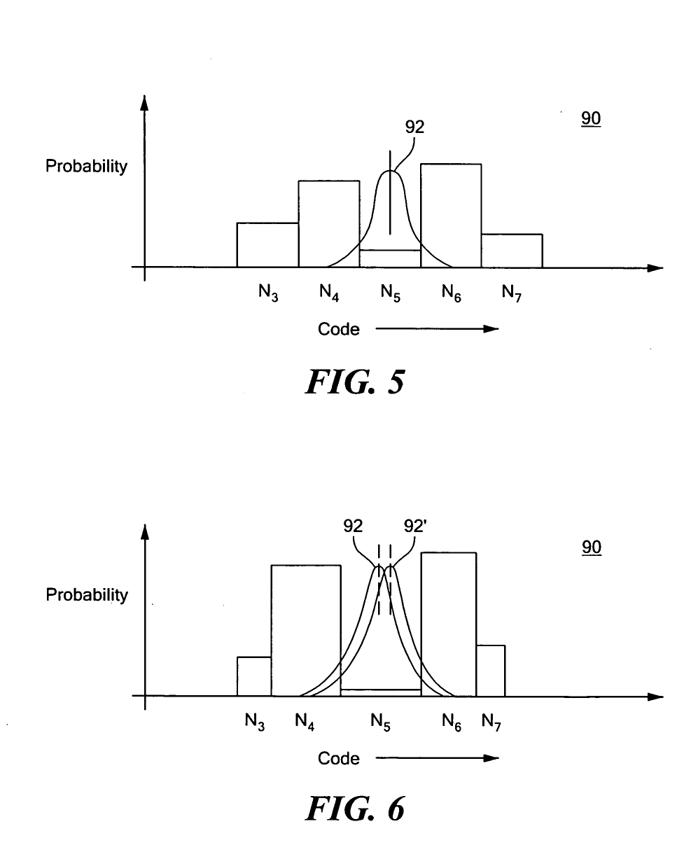

The probability of missing codes occurring using this invention is shown in the histogram 90, FIG. 5. Here the missing code N₅ is recovered by averaging codes N₄ and N₆. Adjacent codes can be made narrower as a side effect here indicated by the presence of codes N₃ and N₇. The average will appear as shown at 92 which although shown as a smooth function for simplicity actually is made up of many small steps. The important point here is that whenever an averaging occurs, N₅, the missing code, will be made to occur simply by the fact of averaging the neighbors of the nearly missing code. As the input voltages change curve 92 will move. For example, if the input voltage increases somewhat, curve 92 will move to 92′, FIG. 6, but it will still be there. In fact, different voltages will provide a number of different positions, namely, in this case, where the number of averages in the stage as shown in FIG. 4 is sixty-four, there will be sixty-four such possible positions for the curve 92, thus the additional six bits of accuracy added by stage 60 from thirteen to nineteen and from stage 62 from nineteen to twenty-five and so on.

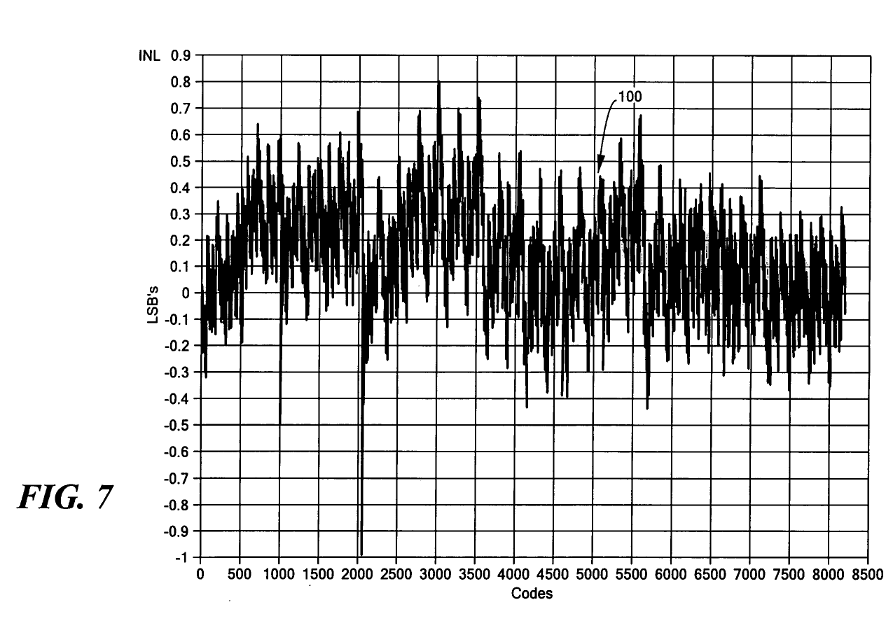

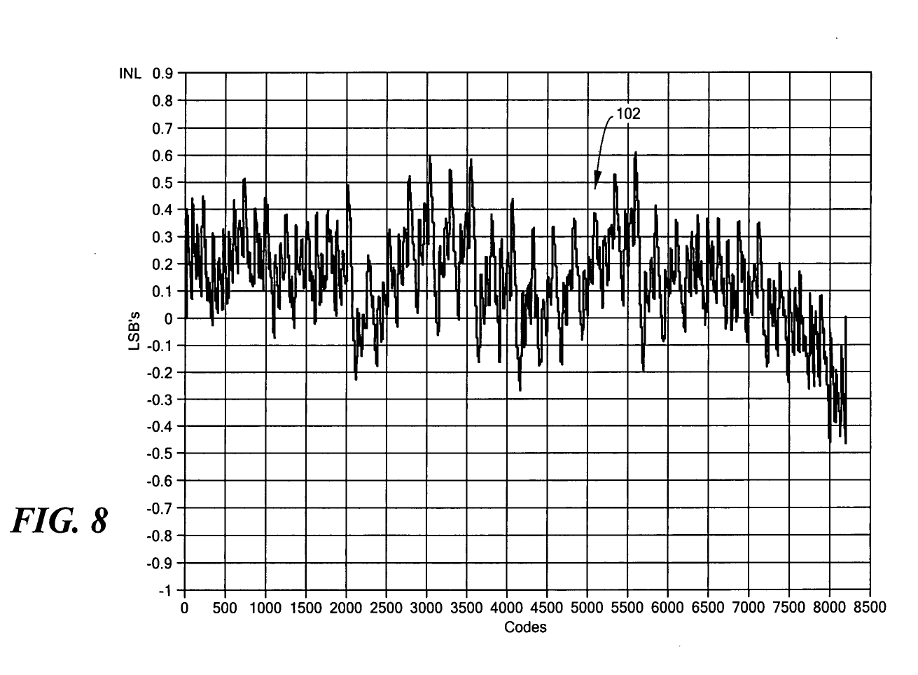

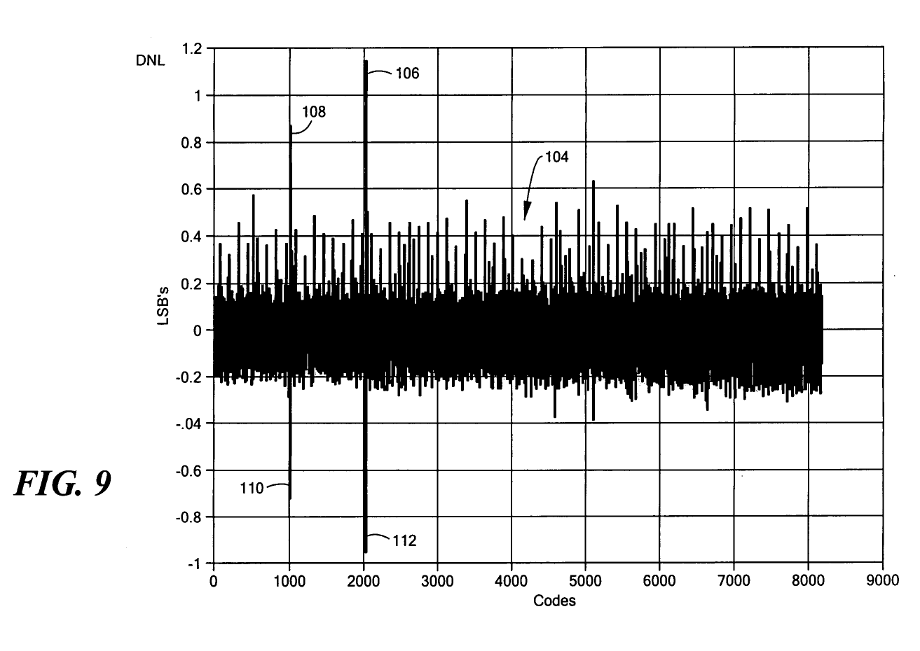

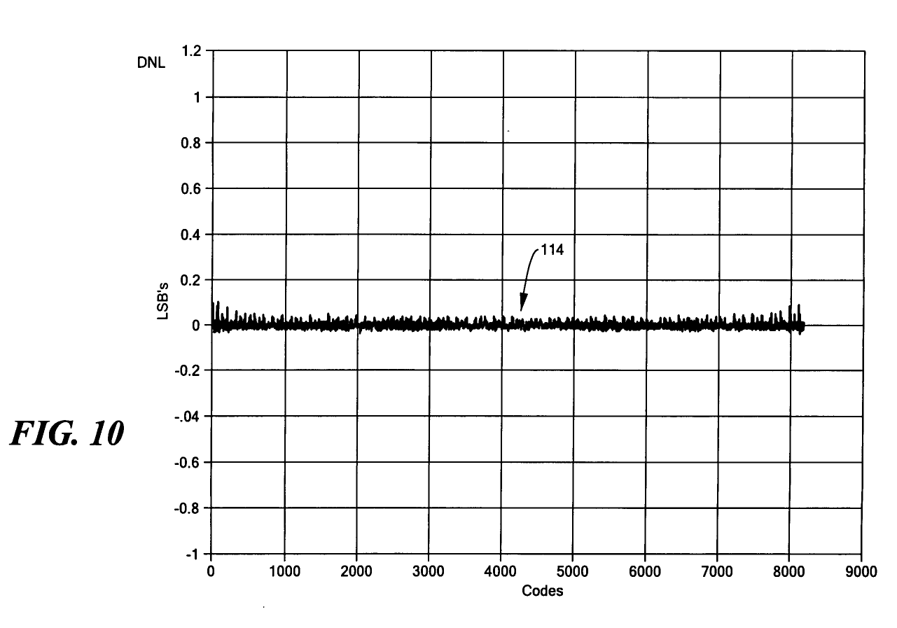

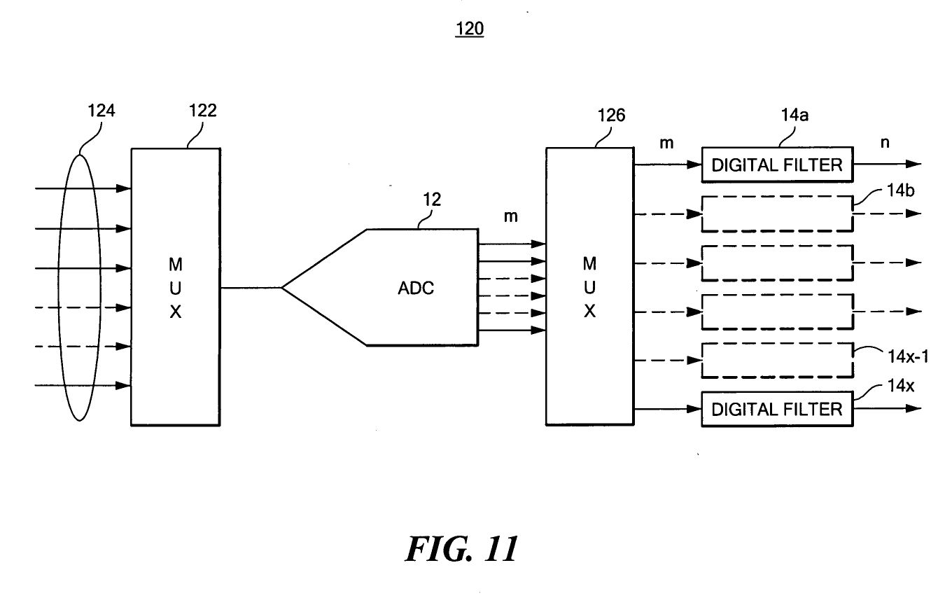

The efficacy of this invention can be seen in FIGS. 7-10. In FIG. 7 there is shown the INL 100 for an analog to digital converter system not using this invention. FIG. 8, shows the INL 102 using the band limiting or averaging filter of this invention in combination with the random noise dither. It can be seen from a comparison of FIG. 7 and FIG. 8 that FIG. 8 provides a much smoother INL. Likewise, FIG. 9 shows a DNL for the same analog to digital converter system not using this invention. Here note that the DNL characteristic 104 has a number of very high excursions 106, and 108 being the two highest in the positive direction and 110 and 112 being the highest in the negative direction. Recall that high positive values while undesirable do not result in missing codes. However, the high negative values, 110, and especially 122 which is nearly −1 LSB are of great concern. The code at this point coinciding to 112 is most likely going to be a missing code. However, employing this invention with the band limiting or averaging technique in the digital filter and defining the analog to digital converter system as the analog converter plus the digital filter and typically packaging them on the same chip, the DNL 114, FIG. 10, has been greatly reduced both in the positive and negative excursions so that there is virtually a guarantee that there will be no missing codes for these reasons. Analog to digital converters such as SAR ADCs can now have the high accuracy once only easily obtainable with ΣΔ analog to digital converters. With this increased resolution and virtual guarantee of no missing codes the system can be implemented in a multiplexed system 120, FIG. 11, where a first mux 122 can select any one of a number of inputs 124 to deliver to analog to digital converter 12. The m outputs of ADC 12 can then be delivered to a second mux 126 that can provide those outputs to anyone of digital filters 14a, through 14x.

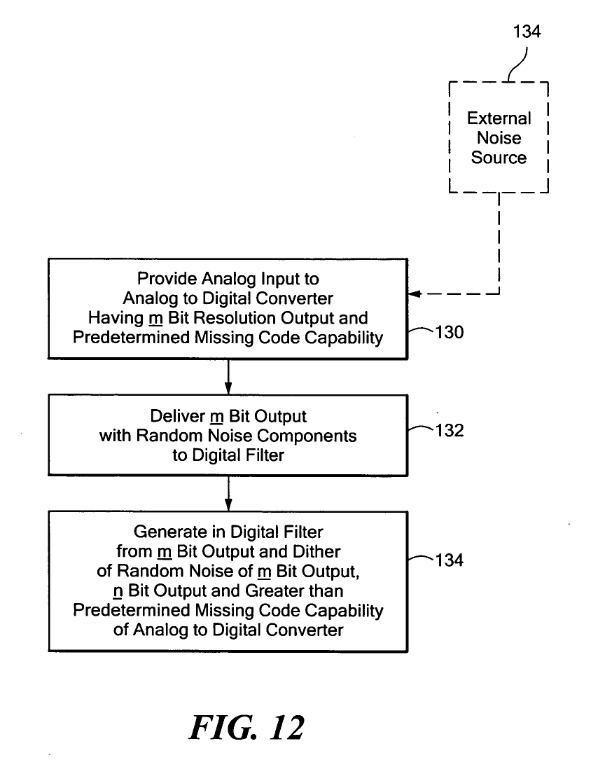

The invention also includes a method which involves providing an analog input to an analog to digital converter having m bit resolution output and predetermined missing code capability, step 130, FIG. 12. The m bit output is then delivered with random noise components to a digital filter, step 132. The random noise may be added or boosted using an external noise source 134 as indicated by components 20, 20′ and 22 in FIG. 1. From the m bit output and the dither of the random noise of the m bit output there is generated in a digital filter n bit output and greater than the predetermined missing code capability of the analog to digital converter, step 134.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the following claims.

What is claimed is:

1. A SAR/pipeline/flash/folding no-missing-code analog to digital converter system comprising:
an analog to digital converter having a significant random noise component relative to its LSB and having a predetermined missing code capability;
a digital filter responsive to the dither introduced by said random noise components of the m bit inputs from said analog to digital converter to provide n bit outputs and greater than the predetermined missing code capability of said analog to digital converters.

2. The analog to digital converter system of claim 1 in which said digital filter and said analog to digital converter are on a single chip.

3. The analog to digital converter system of claim 1 in which m is greater than n and the said filter reduces resolution and recovers missing code.

4. The analog to digital converter system of claim 1 in which m is equal to n and the said filter recovers missing code.

5. The analog to digital converter system of claim 1 in which m is less than n and the said filter increases resolution and recovers missing code.

6. The analog to digital converter system of claim 1 in which said digital filter includes one of a group of low pass, bandpass, highpass, stopband, sinc, IIR and FIR filters.

7. The analog to digital converter system of claim 1 further includes a truncating circuit for reducing the output bit resolution from said digital, filter to a pre-selected lower resolution.

8. The analog to digital converter system of claim 2 further includes an output circuit for delivering the no-missing-codes output of said digital filter off-chip as an output of said system.

9. The analog to digital converter system of claim 1 in which said digital filter includes a plurality of taps for band limiting the m bit inputs.

10. The analog to digital converter system of claim 1 in which said digital filter includes a plurality of taps for averaging the m bit inputs.

11. The analog to digital converter system of claim 1 in which said digital filter increases word width in each successive stage as a function of the number of taps.

12. The analog to digital converter system of claim 1 in which said digital filter increases missing code recovery in each successive stage as a function of the number of taps.

13. The analog to digital converter system of claim 1 in which said random noise includes significant thermal noise.

14. The analog to digital converter system of claim 1 in which said analog to digital converter includes a random noise source for contributing to said random noise.

15. The analog to digital converter system of claim 1 further including a first mux circuit for selectively providing a number of different inputs to said analog to digital converter, a plurality of said digital filters and a second mux circuit for selectively connecting to said analog to digital converter to one of said digital filters.

16. A method of providing a no-missing-code output from an analog to digital converter system comprising:
providing an analog input to an analog to digital converter having a predetermined m bit resolution output and predetermined missing code capability;
delivering said m bit output with random noise components to a digital filter;
generating in said digital filter from said m bit output and the dither of the random noise of the m bit output components an n bit output and greater than the predetermined missing code capability of said analog to digital converter.

17. The method of providing a no-missing-code output from a analog to digital converter system of claim 16 in which said digital filter and said analog to digital converter are on a single chip.

18. The method of providing a no-missing-code output from an analog to digital converter system of claim 16 in which m is greater than n and the said filter reduces resolution and recovers missing codes.

19. The method of providing a no-missing-code output from an analog to digital converter system of claim 16 in which m is equal to n and the said filter recovers missing codes.

20. The method of providing a no-missing-code output from an analog to digital converter system of claim 16 in which m is less than n and the said filter increases resolution and recovers missing codes.

21. The method of providing a no-missing-code output from an analog to digital converter system of claim 16 which further reduces the output bit resolution from said digital filter to a pre-selected lower resolution

22. The method of providing a no-missing-code output from an analog to digital converter system of claim 16 in which said digital filter includes a plurality of taps for band limiting the m bit inputs.

23. The method of providing a no-missing-code output from an analog to digital converter system of claim 16 in which said digital filter includes a plurality of taps for averaging the m bit inputs.

24. The method of providing a no-missing-code output from an analog to digital converter system of claim 16 in which said digital filter increases word width in each successive stage as a function of the number of taps.

25. The method of providing a no-missing-code output from an analog to digital converter system of claim 16 in which said digital filter increases missing code recovery in each successive stage as a function of the number of taps.

26. The method of providing a no-missing-code output from an analog to digital converter system of claim 16 in which said random noise includes significant thermal noise.

27. The method of providing a no-missing-code output from an analog to digital converter system of claim 16 in which said analog to digital converter includes a random noise source for contributing to said random noise.
